(19) United States
(12) Patent Application Publication
(10) Pub. No.: US 2002/0192934 A1
(43) Pub. Date: Dec. 19, 2002

(54) 2-input nor gate with NMOS transistors and PMOS transistors formed on different semiconductor layers

(76) Inventor: Young Soo Jeong, Ichon-shi (KR)

Correspondence Address: JACOBSON HOLMAN, PROFESSIONAL LIMITED LIABILITY COMPANY, 400 SEVENTH STREET, N.W., WASHINGTON, DC, 20004, US

(21) Appl. No.: 09/955,303

(22) Filed: Sep. 19, 2001

(30) Foreign Application Priority Data
Jun. 14, 2001 (KR) 2001-33680

(51) Int. Cl. H01L 21/44; H01L 21/4763

(52) U.S. Cl. 438/598; 438/618; 438/599; 257/401

(57) ABSTRACT

A 2-input NOR gate with NMOS transistors and PMOS transistors formed on different semiconductor layers, and a fabricating method for the same, are disclosed. The NMOS and PMOS transistors of the CMOS transistors are formed on different semiconductor layers unlike in the conventional technique, thereby improving the chip density. Further, the device isolating film forming process can be eliminated, and therefore, the fabrication process can be simplified, while the problems such as punch-through, latch-up and the like can be solved.

### FIELD OF THE INVENTION

The present invention relates to a semiconductor device fabricating technique. Particularly, the present invention relates to a 2-input NOR gate with NMOS transistors and PMOS transistors formed on different semiconductor layers, and a fabricating method for the same.

### BACKGROUND OF THE RELATED ART

FIG. 1 is a circuit diagram showing the conventional 2-input NOR gate. This conventional NOR gate includes: a first PMOS transistor P1 and a first NMOS transistor N1, both of them sharing a first gate, and the first gate being connected to a first input (I/P A); and a second PMOS transistor P2 and a second NMOS transistor N2, both of them sharing a second gate, the second gate being connected to a second input (I/P B).

A first source/drain junction of the first PMOS transistor P1 is connected to an output line O/P, and a first source/drain junction of the second PMOS transistor P2 is connected to a power supply line Vdd. The respective second source/drain junctions of the first and second PMOS transistors P1 and P2 are connected together.

The first source/drain junctions of the first and second NMOS transistors N1 and N2 are commonly connected to the output line O/P, while the second source/drain junctions of the first and second NMOS transistors n1 and N2 are commonly connected to a grounding line Vss.

FIG. 2a is a layout for forming the 2-input NOR gate of FIG. 1 on a substrate.

The layout includes: a p-active region 11A and an n-active region 11B defined on a semiconductor substrate or on a semiconductor layer; a first gate 12 connected to a first input (I/P A), for serving as a gate of the first PMOS transistor P1 and the first NMOS transistor N1; a second gate connected to a second input (I/P B), for serving as a gate of the second PMOS transistor P2 and the second NMOS transistor N2; an output line O/P connected to a first source/drain junction of the first PMOS transistor P1 and the second NMOS transistor N2; a power supply line Vdd connected to a first source/drain junction (not illustrated) of the second PMOS transistor P2 and to the semiconductor substrate or to the semiconductor layer; and a grounding line Vss connected to the respective source/drain junctions of the first NMOS transistor N1 and the second NMOS transistor N2.

FIG. 2b is a sectional view taken along a line X-X′ of FIG. 1a.

As shown in FIGS. 2a and 2b, the conventional 2-input NOR gate is characterized as follows. That is, a device isolating film (not illustrated) is formed on a single semiconductor layer or on a silicon semiconductor substrate 10 by carrying out a LOCOS (local oxidation of silicon) process, thereby isolating the NMOS transistors and the PMOS transistors from each other. Thus, the occurrence of a punch-through is prevented, and consequently, the latch-up characteristics are improved.

Now, the conventional method for forming the NMOS and PMOS transistors on the same semiconductor layer will be described referring to FIGS. 3a to 3d.

First, as shown in FIG. 3a, a field oxide film 22 is formed on a silicon substrate 20 by applying the LOCOS process, thereby isolating the p-well 21A and the n-well 21B from each other.

Then, a first ion-implantation mask (not shown) is formed on the n-well 21B region, and then, a p-type impurity is ion-implanted into a p-well region.

Then, the first ion-implantation mask is removed, and then, a second ion-implantation mask (not shown) is formed on the p-well region. Then, an n-type impurity is ion-implanted into the n-well region, and then, the second ion-implantation mask is removed. Thereafter, a heat treatment is carried out, thereby forming the p-well 21A and the n-well 21B.

As shown in FIG. 3b, a gate insulating film 23 is formed on the silicon substrate 20 on which the p-well 21A and the n-well 21B have been formed, and then, a polysilicon film 24 is formed on the gate insulating film 23, for forming a gate. Then, a third ion-implantation mask 101 is formed on the polysilicon film 24 which has been formed on the p-well region. Then, an n-type impurity such as phosphorus (P) is ion-implanted to form an n-type polysilicon film 24A on the n-well region.

Then, the third ion-implantation mask 101 is removed. Then as shown in FIG. 3c, a fourth ion-implantation mask 102 is formed on the n-type polysilicon film 24A, and then, a p-type impurity such as boron (B) is ion-implanted to form a p-type polysilicon film 24B on the p-well region.

Then, as shown in FIG. 3d, the n-type and p-type polysilicon films 24A and 24B are selectively removed, thereby forming the gates 24C and 24D of the PMOS and NMOS transistors. Then, in order to form source/drains 25 and 26 of the PMOS and NMOS transistors respectively, an ion-implantation process is carried out to form a CMOS transistor.

In the conventional method for forming the 2-input NOR gate, there has to be a device isolating film formed for isolating the PMOS and NMOS transistors from each other. Accordingly, the device area is increased, and if a perfect isolation is not done, due to the process errors, then the product characteristics are aggravated.

### SUMMARY OF THE INVENTION

The present invention is intended to overcome the above described disadvantages of the conventional technique.

Therefore it is an object of the present invention to provide a 2-input NOR gate with NMOS and PMOS transistors formed on different semiconductor layers, and a method for forming the same, in which a device isolating film for isolating the PMOS and NMOS transistors from each other can be eliminated, thereby improving the device density and effectively preventing any deterioration of the device characteristics.

In accordance with an aspect of the present invention, there is provided a 2-input NOR gate with NMOS and PMOS transistors formed on different semiconductor layers, the 2-input NOR gate comprising: a first conduction type first semiconductor layer; a first gate insulating film formed on the first semiconductor layer; a gate of a first transistor and a gate of a second transistor formed on the first gate insulating film; first and second junctions of the first transistor formed on the first semiconductor layer; first and second junctions of the second transistor formed on the first semiconductor layer; a second conduction type second semiconductor layer formed on the first semiconductor layer; a second gate insulating film formed on the second semiconductor layer; a gate of a third transistor and a gate of a fourth transistor formed on the second gate insulating film; first and second junctions of the third transistor formed on the second semiconductor layer; first and second junctions of the fourth transistor formed on the second semiconductor layer; a first input line connected to the gate of the first transistor and to the gate of the third transistor; and a second input line connected to the gates of the second and fourth transistors.

In accordance with another aspect of the present invention, there is provided a 2-input NOR gate with NMOS and PMOS transistors formed on different semiconductor layers, the 2-input NOR gate comprising: a first conduction type first semiconductor layer; a first gate insulating film formed on the first semiconductor layer; a gate of a first transistor and a gate of a second transistor formed on the first gate insulating film; first and second junctions of the first transistor formed on the first semiconductor layer; first and second junctions of the second transistor formed on the first semiconductor layer; a first interlayer insulating film for covering the first semiconductor layer and the gates of the first and second transistors; a first connection part for being contacted to the gate of the first transistor through a first input connecting contact hole, the first input connecting contact hole being formed in the first interlayer insulating film; a second connection part for being contacted to the gate of the second transistor through a second input connecting contact hole, the second input connecting contact hole being formed in the first interlayer insulating film; a third connection part for being contacted to the first junction of the first transistor through a first output line connecting contact hole of the first interlayer insulating film; a fourth connection part for being contacted to the first junction of the second transistor through a first power supply line connecting contact hole of the first interlayer insulating film; a second semiconductor layer formed on the first interlayer insulating film; a second gate insulating film formed on the second semiconductor layer; a gate of the third transistor formed on the second gate insulating film, for being connected to the gate of the first transistor through the first connection part; a gate of the fourth transistor formed on the second gate insulating film, for being connected to the gate of the second transistor through the second connection part; first and second junctions of the third transistor formed on the second semiconductor layer; first and second junctions of the fourth transistor formed on the second semiconductor layer; a second interlayer insulating film for covering the second semiconductor layer and the gates of the third and fourth transistors; a first input line for being connected to the gate of the first transistor and to the gate of the third transistor; and a second input line for being connected to the gate of the second transistor and to the gate of the fourth transistor.

In accordance with still another aspect of the present invention, there is provided a method for forming a 2-input NOR gate with NMOS and PMOS transistors formed on different semiconductor layers comprising the steps of: forming a first gate insulating film on a first semiconductor layer after forming a first active region on it; forming a gate of a first transistor and a gate of a second transistor on the first gate insulating layer; forming first and second junctions of the first transistor and first and second junctions of the second transistor on the first semiconductor layer; forming a first interlayer insulating film on the semiconductor layer (on which the first and second transistors have been formed); selectively etching the first interlayer insulating film, to form a first input connecting contact hole so as to expose the gate of the first transistor, to form a second input connecting contact hole so as to expose the gate of the second transistor, to form a first output line connecting contact hole so as to expose the first junction of the first transistor, and to form a power supply line connecting contact hole so as to expose the first junction of the second transistor; forming a first plug within the first input connecting contact hole, forming a second plug within the second input connecting contact hole, forming a third plug within the first output connecting contact hole, and forming a fourth plug within the first power supply line connecting contact hole; forming a first connection pad in contact with the first plug, forming a second connection pad in contact with the second plug, forming a third connection pad in contact with the third plug, forming a fourth connection pad in contact with the fourth plug, and forming a second semiconductor layer; forming a second gate insulating film on the second semiconductor layer; forming a gate of the third transistor to be connected to the gate of the first transistor through the first plug of the first input connecting contact hole and through the first connection pad, and forming a gate of the fourth transistor to be connected to the gate of the second transistor through the second plug of the second input connecting contact hole; and forming a first input line for being connected to the gate of the first transistor and to the gate of the third transistor, and forming a second input line for being connected to the gate of the second transistor and to the gate of the fourth transistor.

In the conventional 2-input NOR gate, the NMOS and PMOS transistors are formed on the same semiconductor layer or on semiconductor substrate, whereas in the 2-input NOR gate of the present invention, the NMOS and PMOS transistors are formed on different semiconductor layers so as to eliminate the device isolation film forming process.

### BRIEF DESCRIPTION OF THE DRAWINGS

The above object and other advantages of the present invention will become more apparent by describing in detail the preferred embodiment of the present invention with reference to the attached drawings in which:

FIG. 1 is a circuit diagram showing the constitution of the conventional 2-input NOR gate;

FIGS. 2a and 2b are layout and sectional view of the conventional 2-input NOR gate, respectively;

FIGS. 3a to 3d are sectional views showing the fabricating process for the conventional NMOS transistors and PMOS transistors;

FIGS. 4a to 4c illustrate a multi-layer layout of the 2-input NOR gate according to the present invention; and

FIGS. 5a to 5c are sectional views taken along lines A-A′, B-B′ and C-C′ of FIG. 4c, respectively.

### DETAILED DESCRIPTION OF THE PREFERRED EMBODIMENT

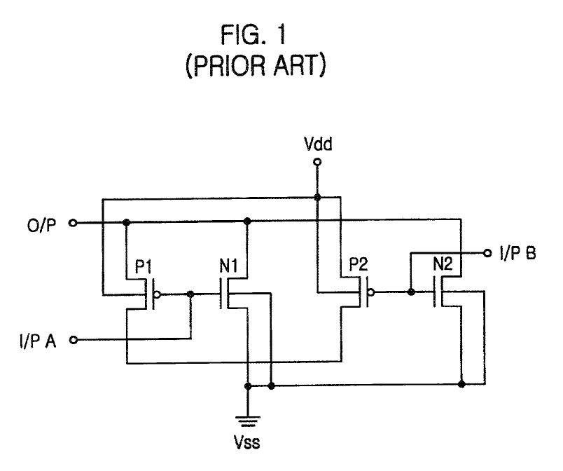

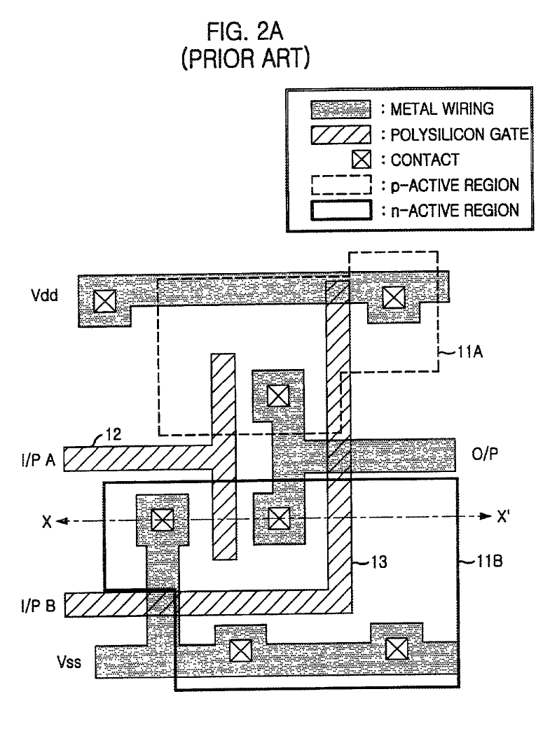

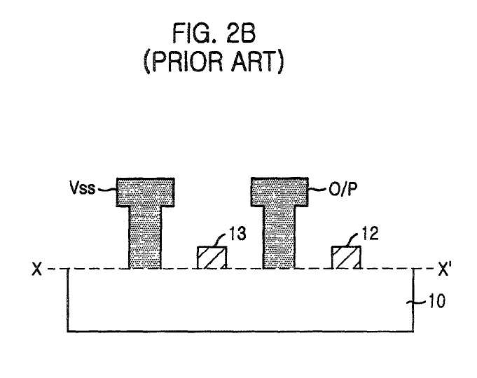

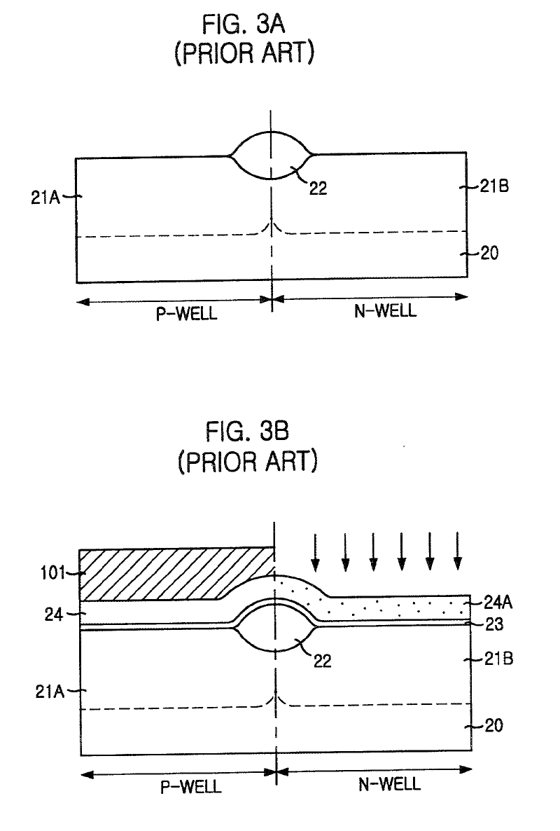

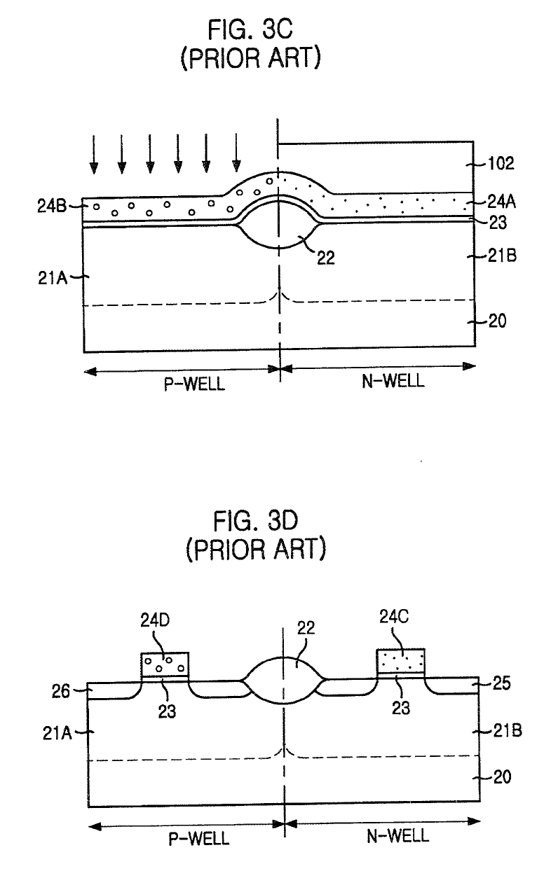

The preferred embodiment of the 2-input NOR gate according to the present invention will be described referring to FIGS. 1, 4a to 4c, and 5a to 5c.

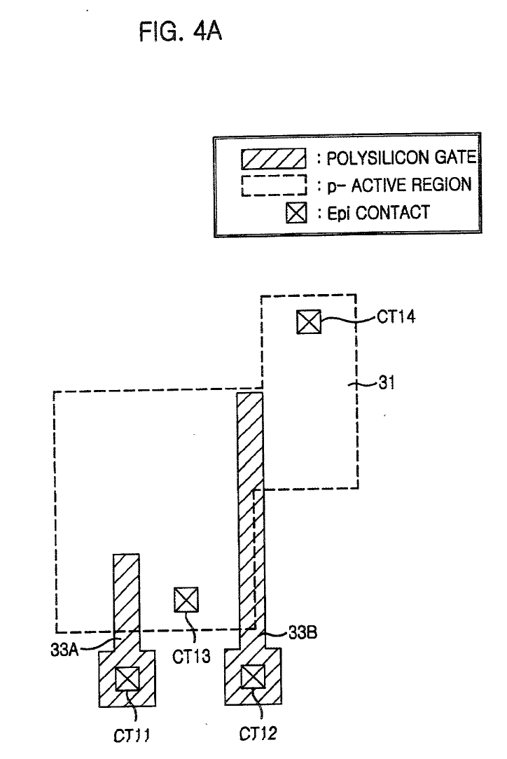

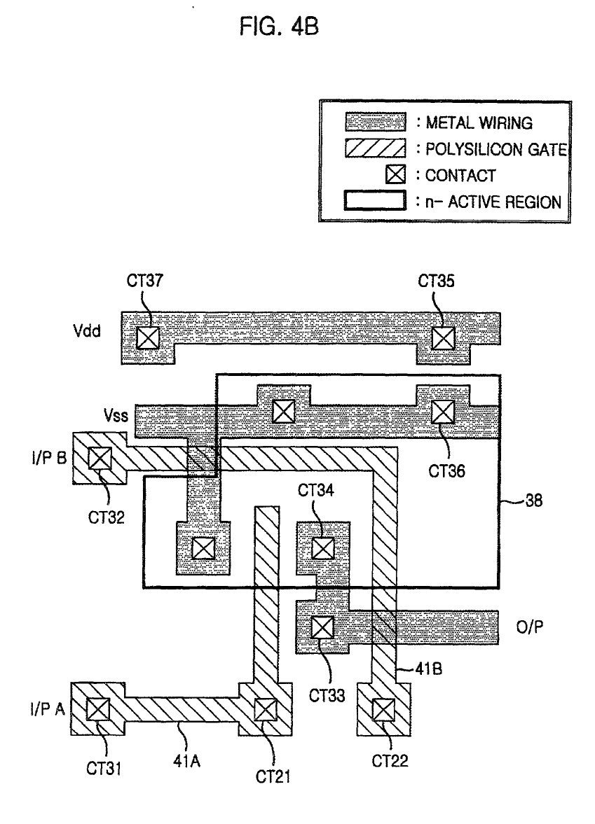

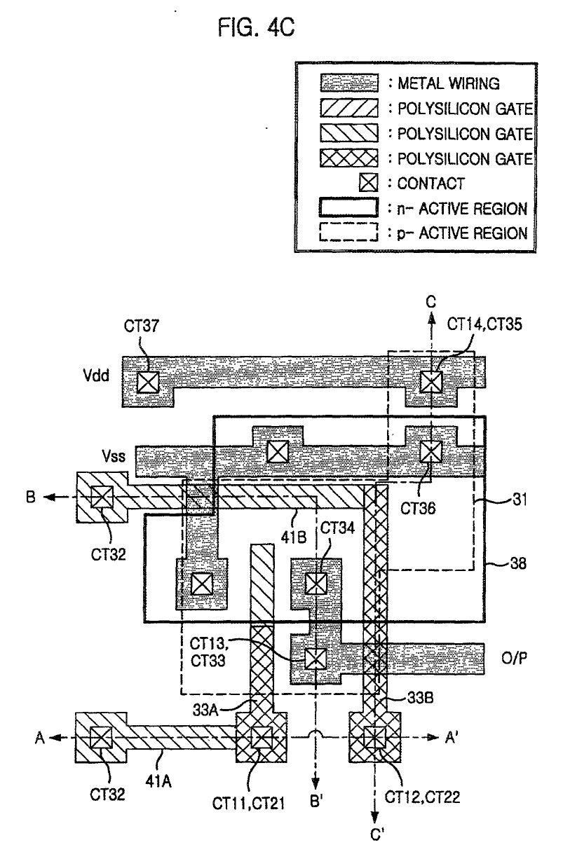

Referring to FIG. 4a, the NOR gate includes: a p-active region 31 of a first PMOS transistor P1 defined on a first semiconductor layer (not shown) (which consists of an n-type semiconductor substrate or an n-type well), with respective source/drains (not shown) of the first PMOS transistor P1 and a second PMOS transistor being formed therein; a first gate 33A overlapped with the p-active region 31 and connected to a first input (I/P A) (See FIG. 4b) so as to serve as the gate of the first PMOS transistor P1; a second gate 33B overlapped with the p-active region 31 and connected to a second input (I/P B) so as to serve as the gate of the second PMOS transistor; a first input connecting contact hole CT11 for connecting the first gate 33A to the first input (I/P A); a second input connecting contact hole CT12 for connecting the second gate 33B to the second input (I/P B); a first output line connecting contact hole CT13 for connecting an output line O/P (See FIG. 4c) to a first source/drain junction (not shown) of the first PMOS transistor P1; and a first power supply line connecting contact hole CT14 for connecting a power supply line Vdd to a first source/drain junction (not shown) of the second PMOS transistor P2.

FIG. 4b includes: an n-active region 38 defined on a p type semiconductor layer, with respective source/drains (not shown) of a first NMOS transistor N1 and a second NMOS transistor being formed therein; a third gate 41A overlapped with the n-active region 38, and connected to the first gate 33A through the third input connecting contact hole CT21 (which is connected to the first input connecting contact hole CT11), and contacted to the first input (I/P A) through a fifth input connecting contact hole CT31, so as to serve as the gate of the first NMOS transistor N1; a fourth gate 41B overlapped with the n-active region 38, and connected to the second gate 33B through the fourth input connecting contact hole CT22 (which is connected to the second input connecting contact hole CT12), and connected to the second input (I/P B) through a sixth input connecting contact hole CT32, so as to serve as the gate of the second NMOS transistor N2; an output line O/P connected to a first source/drain junction (not shown) of the first PMOS transistor through the second output line connecting contact hole CT33 (which is connected to the first output line connecting contact hole CT13), and connected to a first source/drain junction of the second NMOS transistor through the third output line connecting contact hole CT34; a power supply line Vdd connected to a first source/drain junction (not illustrated) of the second PMOS transistor P2 through the second power supply line connecting contact hole CT35 (which is connected to the first power supply line connecting contact hole CT14), and connected to the first semiconductor layer through a third power supply line connecting contact hole CT37; and a grounding line connected to a second source/drain junction (not shown) of the first and second NMOS transistors N1 and N2, and connected to the n-active region 38.

FIG. 4c illustrates a layout that is overlapped with the layouts of FIGS. 4a and 4b.

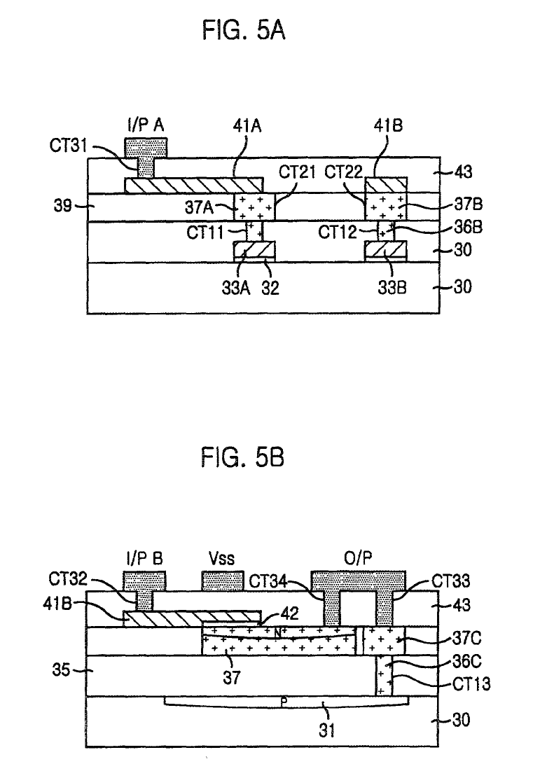

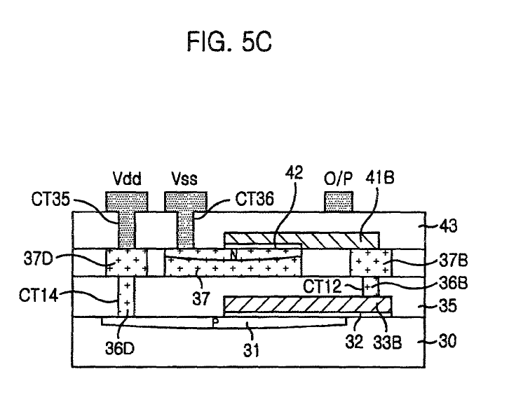

Although there is no illustration in FIGS. 4a to 4c and 5a to 5c, the 2-input NOR gate according to the present invention further includes a wiring for interconnecting the source/drain junctions of the first and second PMOS transistors P1 and P2.

Now the method for forming the 2-input NOR gate according to the present invention will be described referring to FIGS. 5a to 5c. FIG. 5a is a sectional view taken along the line A-A′ of FIG. 4c, FIG. 5b is a sectional view taken along the line B-B′ of FIG. 4c, and FIG. 5c is a sectional view taken along the line C-C′ of FIG. 4c.

First, a p-active region 31 is defined on an n-type semiconductor substrate or on a first semiconductor layer 30 (forming an n-well). Then a first gate insulating film 32 is formed, and then, a first polysilicon film is deposited and patterned to form a first gate 33A and a second gate 33B.

An ion-implantation is carried out to form first and second source/drain junctions (not illustrated) of the first and second PMOS transistors P1 and P2 on the p-active region. A first BPSG (borophosphosilicate glass) film 35 is deposited, and then, a selective etching is carried out.

Thus, there are formed: a first input connecting contact hole CT11 to expose the first gate 33A; a second input connecting contact hole CT12 to expose the second gate 33B; a first output line connecting contact hole CT13 to expose the first source/drain junction of the first PMOS transistor P1 (which is connected to the output line O/P); and a first power supply line connecting contact hole CT14 to expose the first source/drain junction of the second PMOS transistor (which is connected to the power supply line Vdd).

A first epitaxial growing is carried out to form a second polysilicon film, and then, an ion-implantation is carried out to lower the resistivity.

In order to make the second polysilicon film remain only in the contact holes, a chemical-mechanical polishing is carried out. Thus first to fourth plugs 36A, 36B, 36C and 36D are formed for the first power supply line connecting contact hole CT11, for the second input connecting contact hole CT12, for the first output line connecting contact hole CT13 and for the first power supply line connecting contact hole CT14.

A second epitaxial growing is carried out to form a third polysilicon film on the first to fourth plugs 36A, 36B, 36C and 36D.

The third polysilicon film is patterned to form: a first connection pad 37A contacted to the first plug; a second semiconductor layer 37 for serving as an n-active region 38; a second connection pad 37B contacted to the second plug; a third connection pad 37C contacted to the third plug 36C; and a fourth connection pad 37D contacted to the fourth plug 36D.

In order to insulate the second semiconductor layer 37 and the first to fourth connection pads 37A, 37B, 37C and 37D from each other, there is formed an insulating film 39 on the first BPSG film 35.

A second gate insulating film 40 is formed on the second semiconductor layer 37, and then, a fourth polysilicon film is deposited and patterned. Thus there are formed: a third gate 41A connected through the first plug 36A of the third input connecting contact hole CT21 to the first gate 33A; and a fourth gate 41B connected through the second plug 36B of the fourth input connecting contact hole CT22 to the second gate 33B.

An ion-implantation is carried out to form respective source/drain junctions (not illustrated) of the first and second NMOS transistors N1 and N2. A second BPSG film 43 is deposited and selectively patterned to form the following elements.

That is, there are formed: a fifth input connecting contact hole CT31 for exposing the third gate 41A; a sixth input connecting contact hole CT32 for exposing the fourth gate 41B; a second output line connecting contact hole CT33 for exposing the third connection pad 37C; at least one third output line connecting contact hole CT34 for exposing the first source/drain junctions of the first and second NMOS transistors N1 and N2; a second power supply line connecting contact hole CT35; respective second source/drain junctions (not illustrated) of the first and second NMOS transistors N1 and N2; and at least one grounding line connecting contact hole CT36 for exposing the n-active region 38.

The second BPSG film 43, the insulating film 39 and the first BPSG film 35 are selectively etched to form a third power supply line connecting contact hole CT37 for exposing the first semiconductor layer 30.

A metal film is deposited and patterned to form the following elements. That is, there are formed: a power supply line Vdd for being connected through the second power supply line connecting contact hole CT35 to the fourth connection pad 37D, and for being connected through the third power supply line connecting contact hole CT37 to the first semiconductor layer 30; a grounding line Vss connected through the grounding line connecting contact hole CT36 to the respective second source/drain junctions of the first and second NMOS transistors N1 and N2, and to the n-active region 38; a first input line (I/P A) connected through the fifth input connecting contact hole CT31 to the third gate 41A; a second input line (I/P B) connected through the sixth input connecting contact hole CT32 to the fourth gate 41B; and an output line O/P connected through the second output line connecting contact hole CT33 to the third connection pad 37C, and connected through the third output line connecting contact hole CT34 to the second semiconductor layer 37.

According to the present invention as described, the NMOS and PMOS transistors of the CMOS transistors are formed on different semiconductor layers unlike in the conventional technique, thereby improving the chip density. Further, the device isolation film forming process can be eliminated, and therefore, the fabrication process can be simplified, while the problems such as punch-through, latch-up and the like can be solved.

In the above, the present invention was described based on the specific preferred embodiment and the attached drawings, but it should be apparent to those ordinarily skilled in the art that various changes and modifications can be added without departing from the spirit and scope of the present invention, which will be defined in the appended claims.

What is claimed is:

1. A 2-input NOR gate with NMOS and PMOS transistors formed on different semiconductor layers, comprising:
a first conduction type first semiconductor layer;
a first gate insulating film formed on the first semiconductor layer;
a gate of a first transistor and a gate of a second transistor formed on the first gate insulating film;
first and second junctions of the first transistor formed on the first semiconductor layer;
first and second junctions of the second transistor formed on the first semiconductor layer;
a second conduction type second semiconductor layer formed on the first semiconductor layer;
a second gate insulating film formed on the second semiconductor layer;
a gate of a third transistor and a gate of a fourth transistor formed on the second gate insulating film;
first and second junctions of the third transistor formed on the second semiconductor layer;
first and second junctions of the fourth transistor formed on the second semiconductor layer;
a first input line connected to the gate of the first transistor and to the gate of the third transistor; and
a second input line connected to the gates of the second and fourth transistors.

2. The 2-input NOR gate as claimed in claim 1, wherein the first and second transistors are PMOS transistors; and the third and fourth transistors are NMOS transistors.

3. The 2-input NOR gate as claimed in claim 2, further comprising:
an output line connected to the first junction of the first transistor and to the first junction of the fourth transistor;
a power supply line connected to the second junction of the second transistor and to the first semiconductor layer; and
a grounding line connected to the second junctions of the third and fourth transistors and to the second semiconductor layer.

4. A 2-input NOR gate with NMOS and PMOS transistors formed on different semiconductor layers, comprising:
a first conduction type first semiconductor layer;
a first gate insulating film formed on the first semiconductor layer;
a gate of a first transistor and a gate of a second transistor formed on the first gate insulating film;
first and second junctions of the first transistor formed on the first semiconductor layer;
first and second junctions of the second transistor formed on the first semiconductor layer;
a first interlayer insulating film for covering the first semiconductor layer and the gates of the first and second transistors;
a first connection part for being contacted to the gate of the first transistor through a first input connecting contact hole, the first input connecting contact hole being formed in the first interlayer insulating film;
a second connection part for being contacted to the gate of the second transistor through a second input connecting contact hole, the second input connecting contact hole being formed in the first interlayer insulating film;
a third connection part for being contacted to the first junction of the first transistor through a first output line connecting contact hole of the first interlayer insulating film;
a fourth connection part for being contacted to the first junction of the second transistor through a first power supply line connecting contact hole of the first interlayer insulating film;
a second semiconductor layer formed on the first interlayer insulating film;
a second gate insulating film formed on the second semiconductor layer;
a gate of the third transistor formed on the second gate insulating film, for being connected to the gate of the first transistor through the first connection part;
a gate of the fourth transistor formed on the second gate insulating film, for being connected to the gate of the second transistor through the second connection part;
first and second junctions of the third transistor formed on the second semiconductor layer;
first and second junctions of the fourth transistor formed on the second semiconductor layer;
a second interlayer insulating film for covering the second semiconductor layer and the gates of the third and fourth transistors;
a first input line for being connected to the gate of the first transistor and to the gate of the third transistor; and
a second input line for being connected to the gate of the second transistor and to the gate of the fourth transistor.

5. The 2-input NOR gate as claimed in claim 4, wherein the first and second transistors are PMOS transistors; and the third and fourth transistors are NMOS transistors.

6. The 2-input NOR gate as claimed in claim 5, wherein:
the first connection part comprises: a first plug formed within the first input connecting contact hole, the first input connecting contact hole be i being formed in the first interlayer insulating film so as to expose the gate of the first transistor; and a first connection pad formed on the first interlayer insulating film so as to be contacted to the first plug;
the second connection part including a second plug formed within the second input connecting contact hole, the second input connecting contact hole being formed in the first interlayer insulating film so as to expose the gate of the second transistor; and a second connection pad formed on the first interlayer insulating film so as to be contacted to the second plug;
the third connection part including a third plug formed within the first output line connecting contact hole, the first output line connecting contact hole being formed in the first interlayer insulating film so as to expose the first junction of the first transistor; and a third connection pad formed on the first interlayer insulating film so as to be contacted to the third plug; and
the fourth connection part including a fourth plug formed within the first power supply line connecting contact hole, the first power supply line connecting contact hole being formed in the first interlayer insulating film so as to expose the first junction of the second transistor; and a fourth connection pad formed on the first interlayer insulating film so as to be contacted to the fourth plug.

7. The 2-input NOR gate as claimed in claim 6, further comprising:
a fifth input contact hole formed in the second interlayer insulating film, for exposing the gate of the third transistor;
a sixth input contact hole formed in the second interlayer insulating film, for exposing the gate of the fourth transistor;
a second output line connecting contact hole for exposing the third connection part;
at least one third output line connecting contact hole for exposing the first junctions of the third and fourth transistors;
at least one grounding line connecting contact hole for exposing the second semiconductor layer and the second junctions of the third and fourth transistors; and
a third power supply line connecting contact hole for exposing the second interlayer insulating film and the first semiconductor layer.

8. The 2-input NOR gate as claimed in claim 7, further comprising:
a power supply line for being contacted to the fourth connection pad through the second power supply line connecting contact hole, and for being contacted to the first semiconductor layer through the third power supply line connecting contact hole;
a grounding line for being connected to the second semiconductor layer and to the second junctions of the third and fourth transistors through the grounding line connecting contact hole; and
an output line for being connected to the third connection pad through the second output line connecting contact hole, and for being connected to the second semiconductor layer through the third output line connecting contact hole.

9. The 2-input NOR gate as claimed in claim 8, further comprising:
a plurality of insulating films for respectively insulating the first connection pad, the second connection pad, the third connection pad, the fourth connection pad and the second semiconductor layer.

10. A method for forming a 2-input NOR gate with NMOS and PMOS transistors formed on different semiconductor layers, comprising the steps of:
forming a first gate insulating film on a first semiconductor layer after forming a first active region on it;
forming a gate of a first transistor and a gate of a second transistor on the first gate insulating layer;
forming first and second junctions of the first transistor and, forming first and second junctions of the second transistor on the first semiconductor layer;
forming a first interlayer insulating film on the semiconductor layer, on which the first and second transistors have been formed;
selectively etching the first interlayer insulating film, to form a first input connecting contact hole so as to expose the gate of the first transistor, to form a second input connecting contact hole so as to expose the gate of the second transistor, to form a first output line connecting contact hole so as to expose the first junction of the first transistor, and to form a power supply line connecting contact hole so as to expose the first junction of the second transistor;
forming a first plug within the first input connecting contact hole, forming a second plug within the second input connecting contact hole, forming a third plug within the first output connecting contact hole, and forming a fourth plug within the first power supply line connecting contact hole;
forming a first connection pad in contact with the first plug, forming a second connection pad in contact with the second plug, forming a third connection pad in contact with the third plug, forming a fourth connection pad in contact with the fourth plug, and forming a second semiconductor layer;
forming a second gate insulating film on the second semiconductor layer;
forming a gate of the third transistor to be connected to the gate of the first transistor through the first plug of the first input connecting contact hole and the first connection pad, and forming a gate of the fourth transistor to be connected to the gate of the second transistor through the second plug of the second input connecting contact hole; and
forming a first input line for being connected to the gate of the first transistor and to the gate of the third transistor, and forming a second input line for being connected to the gate of the second transistor and to the gate of the fourth transistor.

11. The method as claimed in claim 10, wherein the first and second transistors are PMOS transistors; and the third and fourth transistors are NMOS transistors.

12. The method as claimed in claim 11, further comprising the steps of:
forming a second interlayer insulating film after forming the gate of the third transistor and the gate of the fourth transistor;
forming a fifth input contact hole formed in the second interlayer insulating film, for exposing the gate of the third transistor; a sixth contact hole formed in the second interlayer insulating film, for exposing the gate of the fourth transistor; a second output line connecting contact hole for exposing the third connection part; at least one third output line connecting contact hole for exposing the first junctions of the third and fourth transistors; at least one grounding line connecting contact hole for exposing the second semiconductor layer and the second junctions of the third and fourth transistors; and a third power supply line connecting contact hole for exposing the second interlayer insulating film and the first semiconductor layer; and
forming a power supply line for being contacted to the fourth connection pad through the second power supply line connecting contact hole, and for being contacted to the first semiconductor layer through the third power supply line connecting contact hole; a grounding line for being connected to the second semiconductor layer and to the second junctions of the third and fourth transistors through the grounding line connecting contact hole; and an output line for being connected to the third connection pad through the second output line connecting contact hole, and for being connected to the second semiconductor layer through the third output line connecting contact hole.

13. The method as claimed in claim 12, wherein the first input line, the second input line, the power supply line, the grounding line and the output line are formed simultaneously.

14. The method as claimed in claim 11, wherein the step of forming the first to fourth plugs comprises the sub-steps of:
forming an epitaxial polysilicon film;
varying out an ion-implantation into the epitaxial polysilicon film; and
carrying out a chemical mechanical polishing on the epitaxial polysilicon film.

15. The method as claimed in claim 11, wherein the step of forming the first to fourth connection pads and the second semiconductor layer comprises the sub-steps of:
carrying out an ion-implantation into the epitaxial polysilicon film; and
carrying out a chemical mechanical polishing on the epitaxial polysilicon film.
